(19) United States
(12) Patent Application Publication
(10) Pub. No.: US 2026/0293612 A1
(43) Pub. Date: Sep. 24, 2026

(54) SHEET AFFIXING APPARATUS

(71) Applicant: DISCO CORPORATION, Tokyo (JP)

(72) Inventor: Kazuma Sekiya, Tokyo (JP)

(21) Appl. No.: 19/350,690

(22) Filed: Oct. 6, 2025

(30) Foreign Application Priority Data
Mar. 18, 2025 (JP) 2025-043358

(51) Int. Cl. H10P 72/78; B23K 37/04; H10P 54/00

(52) U.S. Cl. CPC H10P 72/78; B23K 37/04; H10P 54/00

(57) ABSTRACT

A sheet affixing apparatus includes a work holding table that includes a work holding surface, a frame holding table that includes a frame holding surface surrounding the work holding table and that holds a frame on the frame holding surface in a state in which a workpiece held on the work holding surface and a sheet at a central portion of the frame face each other at a distance from each other and the sheet is bent such that a central portion of the sheet is farther from the workpiece than an outer circumferential portion of the sheet, a pressing member, and a moving mechanism that affixes the sheet to the workpiece by moving the pressing member, and the work holding and frame holding tables relative to one another in a state in which the sheet is pressed against the workpiece by the pressing member.

### BACKGROUND OF THE INVENTION

### Field of the Invention

The present invention relates to a sheet affixing apparatus that, with respect to a frame unit including an annular frame and a sheet affixed to the frame in a manner closing an opening at a central portion of the frame, affixes the sheet at the central portion of the frame to a workpiece. Moreover, the present invention relates to a sheet affixing method of affixing a sheet at a central portion of a frame to a workpiece and a chip manufacturing method of, after affixing a sheet at a central portion of a frame to a workpiece, dividing the workpiece into a plurality of chips.

### Description of the Related Art

There is known an adhesive tape affixing apparatus that forms a work unit in which a workpiece, an adhesive tape, and an annular frame are integrated, by affixing the adhesive tape such as a dicing tape, which is affixed to the annular frame in a manner closing an opening at a central portion of the annular frame, to the workpiece such as a semiconductor wafer (see, for example, Japanese Patent Laid-open No. 2011-086687).

In the adhesive tape affixing apparatus described in Japanese Patent Laid-open No. 2011-086687, when the workpiece, the adhesive tape, and the frame are to be integrated, first, the workpiece and the frame are held under suction on a support table in a state in which the workpiece is placed on the opening portion of the frame.

Next, one end portion of the adhesive tape disposed above the workpiece and the frame is pressed against the frame and the workpiece by a roller, and thereafter, the frame and the workpiece are moved relative to the roller in a state in which the roller is spatially fixed in position.

As a result, the adhesive tape is affixed to an upper surface of the frame in a manner closing the opening portion of the frame, and is also affixed to an upper surface of the workpiece, forming a work unit in which the workpiece, the adhesive tape, and the frame are integrated.

Unlike this method, in a case where, first, a frame unit in which an adhesive tape is affixed to a frame in a manner closing an opening portion of the frame is formed, and then, the adhesive tape of the frame unit is affixed to the workpiece, to thereby form a work unit, a portion of the adhesive tape sometimes comes into contact with the workpiece before the adhesive tape is pressed against the workpiece by a roller.

In a case where a portion of the adhesive tape comes into contact with the workpiece prior to pressing of the adhesive tape against the workpiece by a roller as described above, pressing the adhesive tape against the workpiece by the roller and then moving the frame and the workpiece relative to the roller or the roller relative to the frame and the workpiece cause such problems that air bubbles are formed between the adhesive tape and the workpiece or that wrinkles are formed in the adhesive tape.

Note that similar problems may also occur in sheets other than an adhesive tape; similar problems may also occur in a thermocompression bonding sheet which has no adhesive layer and which is affixed to a workpiece by being thermocompression-bonded to the workpiece. Air bubbles, wrinkles, or the like should be prevented from being formed when a sheet including an adhesive tape or a sheet such as a thermocompression bonding sheet is affixed to a workpiece.

### SUMMARY OF THE INVENTION

The present invention has been made in light of the abovementioned problems, and one object of the present invention is to reduce the possibility of air bubbles, wrinkles, or the like being formed in a sheet when a work unit is formed.

In accordance with an aspect of the present invention, there is provided a sheet affixing apparatus that, with respect to a frame unit including an annular frame and a sheet affixed to the frame in a manner closing an opening at a central portion of the frame, affixes the sheet at the central portion of the frame to a workpiece. The sheet affixing apparatus includes a work holding table including a work holding surface that holds the workpiece, a frame holding table including a frame holding surface that is disposed in such a manner as to surround the work holding table and that holds the frame of the frame unit, and holding the frame on the frame holding surface in a state in which the workpiece held on the work holding surface and the sheet at the central portion of the frame face each other at a distance from each other and the sheet is bent such that a central portion of the sheet is farther from the workpiece than an outer circumferential portion of the sheet, a pressing member that sandwiches the sheet held by the frame holding table between the pressing member and the workpiece held by the work holding surface, and presses the sheet against the workpiece, and a moving mechanism that affixes the sheet to the workpiece by moving the pressing member, and the work holding table and the frame holding table relative to one another in a state in which the pressing member is pressing the sheet against the workpiece.

Preferably, the work holding surface is disposed to face downward or obliquely downward.

Further, preferably, the frame holding surface is protruding more than the work holding surface in a thickness direction of the work holding table.

Further, preferably, the sheet affixing apparatus further includes an adjusting mechanism that adjusts a position of the frame holding surface relative to the work holding surface by moving the work holding table and the frame holding table relative to each other along a thickness direction of the work holding table.

Further, preferably, a thickness direction of the work holding table and a vertical direction as a downward direction form an angle of 30 degrees or less.

Further, preferably, the sheet affixing apparatus further includes both or one of a first heating section that heats the pressing member and a second heating section that heats the work holding table.

In accordance with another aspect of the present invention, there is provided a sheet affixing method that, with respect to a frame unit including an annular frame and a sheet affixed to the frame in a manner closing an opening at a central portion of the frame, affixes the sheet at the central portion of the frame to a workpiece. The sheet affixing method includes holding the workpiece on a work holding surface of a work holding table that holds the workpiece, after the workpiece is held on the work holding surface, holding the frame on a frame holding surface that is included in a frame holding table, that is disposed in such a manner as to surround the work holding table, and that holds the frame of the frame unit, and causing the workpiece held on the work holding surface and the sheet at the central portion of the frame to face each other at a distance from each other in a state in which the sheet is bent such that a central portion of the sheet is farther from the workpiece than an outer circumferential portion of the sheet, and after the frame is held on the frame holding surface, affixing the sheet to the workpiece by moving a pressing member, and the work holding table and the frame holding table relative to one another in a state in which the sheet is sandwiched between the pressing member and the workpiece and is pressed against the workpiece by the pressing member.

Preferably, the work holding surface is disposed to face downward or obliquely downward.

Further, preferably, the sheet affixing method further includes, before the workpiece is held on the work holding surface, forming the frame unit by affixing an outer circumferential portion of the sheet to one surface of the frame in a manner closing the opening at the central portion of the frame, with use of a holding table different from the work holding table and the frame holding table.

Further, preferably, the sheet affixing method further includes, before the sheet is affixed to the workpiece, adjusting the frame holding surface to a position protruding more than the work holding surface in a thickness direction of the work holding table, by moving the frame holding table and the work holding table relative to each other in the thickness direction of the work holding table.

Further, preferably, in the affixing the sheet to the workpiece, the sheet is affixed to the workpiece in a state in which both or one of a first heating section that heats the pressing member and a second heating section that heats the work holding surface is heated.

In accordance with a further aspect of the present invention, there is provided a chip manufacturing method of dividing a workpiece into a plurality of chips after, with respect to a frame unit including an annular frame and a sheet affixed to the frame in a manner closing an opening at a central portion of the frame, affixing the sheet at the central portion of the frame to the workpiece. The chip manufacturing method includes holding the workpiece on a work holding surface of a work holding table that holds the workpiece, after the workpiece is held on the work holding surface, holding the frame on a frame holding surface that is included in a frame holding table, that is disposed in such a manner as to surround the work holding table, and that holds the frame of the frame unit, and causing the workpiece held on the work holding surface and the sheet at the central portion of the frame to face each other at a distance from each other in a state in which the sheet is bent such that a central portion of the sheet is farther from the workpiece than an outer circumferential portion of the sheet, after the frame is held on the frame holding surface, affixing the sheet to the workpiece by moving a pressing member, and the work holding table and the frame holding table relative to one another in a state in which the sheet is sandwiched between the pressing member and the workpiece and is pressed against the workpiece by the pressing member, and after the sheet is affixed to the workpiece, dividing the workpiece into a plurality of chips by dividing the workpiece along a plurality of projected dividing lines that are set on one surface of the workpiece and that intersect each other, the workpiece being provided with a device in each of a plurality of regions partitioned by the plurality of projected dividing lines.

The sheet affixing apparatus according to the aspect of the present invention includes the frame holding table including the frame holding surface that holds the frame in a state in which the workpiece held on the work holding surface of the work holding table and the sheet at the central portion of the frame face each other at a distance from each other and the sheet is bent such that the central portion of the sheet is farther from the workpiece than the outer circumferential portion of the sheet.

For example, since the central portion of the sheet gets farther from the workpiece than the outer circumferential portion of the sheet by the weight of the sheet itself due to the action of gravity, the portion of the sheet can be prevented from coming into contact with the workpiece prior to pressing of the sheet against the workpiece by the pressing member. Thus, moving the pressing member, and the work holding table and the frame holding table relative to one another by the moving mechanism in a state in which the sheet is pressed against the workpiece by the pressing member can reduce the possibility of air bubbles, wrinkles, or the like being formed in the sheet when the work unit is formed.

The sheet affixing method according to the other aspect of the present invention includes holding the frame on the frame holding surface, causing the workpiece held on the work holding surface and the sheet at the central portion of the frame to face each other at a distance from each other in a state in which the sheet is bent such that the central portion of the sheet is farther from the workpiece than the outer circumferential portion of the sheet, and affixing the sheet to the workpiece by moving the pressing member, and the work holding table and the frame holding table relative to one another in a state in which the sheet is sandwiched between the pressing member and the workpiece and is pressed against the workpiece by the pressing member.

Also in the sheet affixing method, for example, the central portion of the sheet gets farther from the workpiece than the outer circumferential portion of the sheet by the weight of the sheet itself, so that a portion of the sheet can be prevented from coming into contact with the workpiece prior to pressing of the sheet against the workpiece by the pressing member. Accordingly, the possibility of air bubbles, wrinkles, or the like being formed in the sheet when the work unit is formed can be reduced.

The chip manufacturing method according to the further aspect of the present invention includes the sheet affixing method described above. Hence, the possibility of air bubbles, wrinkles, or the like being formed in the sheet when the work unit is formed can be reduced, and the possibility of any processing defects occurring at the time of dividing the workpiece affixed to the sheet can also be reduced.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a side view of a sheet affixing apparatus;

FIG. 1B is a bottom view of a work holding table and a frame holding table;

FIG. 2 is a flowchart illustrating a device chip manufacturing method;

FIG. 3A is a side view illustrating a frame unit forming step;

FIG. 3B is a perspective view of a frame unit;

FIG. 4 is a view illustrating a relative moving step of moving a frame holding surface and a work holding surface relative to each other;

FIG. 5A is a view illustrating a work holding step;

FIG. 5B is a bottom view of a workpiece, the work holding table, and the frame holding table in the work holding step;

FIG. 6A is a view illustrating a frame unit holding step;

FIG. 6B is a bottom view of the frame unit and other members in the frame unit holding step;

FIG. 7A is a view illustrating a state at the time when an affixing step is started;

FIG. 7B is a bottom view of the frame unit and other members at the time when the affixing step is started;

FIG. 8A is a view illustrating a state in the middle of the affixing step;

FIG. 8B is a bottom view of the frame unit and other members in the middle of the affixing step;

FIG. 9A is a view illustrating a state at the time when the affixing step is ended;

FIG. 9B is a bottom view of the frame unit and other members at the time when the affixing step is ended;

FIG. 10 is a perspective view of the work unit;

FIG. 11A is a partially sectional side view illustrating a dividing step;

FIG. 11B is a perspective view of one device chip;

FIG. 12A is a view illustrating a state at the time when an affixing step according to a second embodiment of the present invention is started; and

FIG. 12B is a view illustrating a state at the time when an affixing step according to a modification of the second embodiment is started.

### DETAILED DESCRIPTION OF THE PREFERRED EMBODIMENTS

### First embodiment

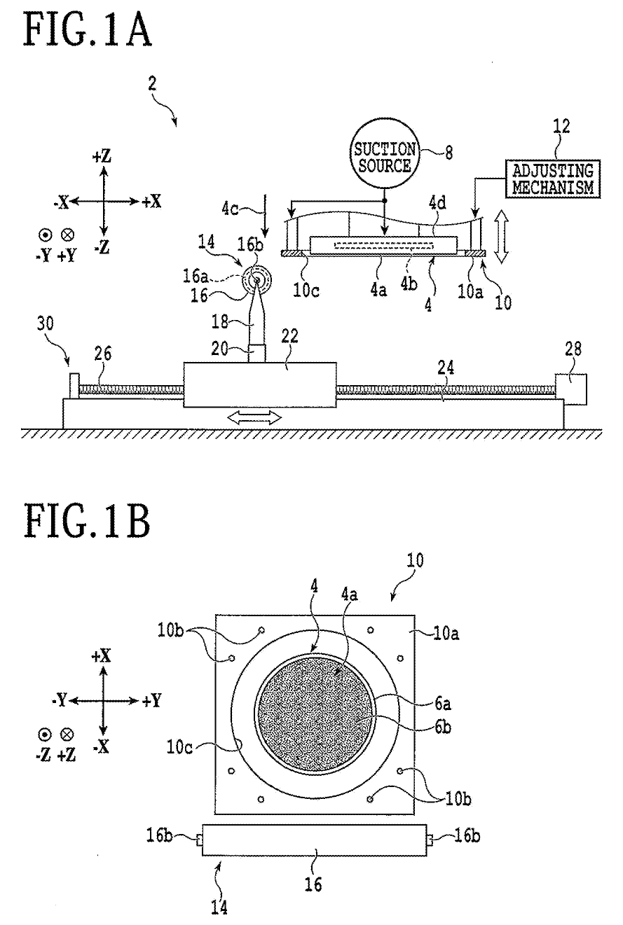

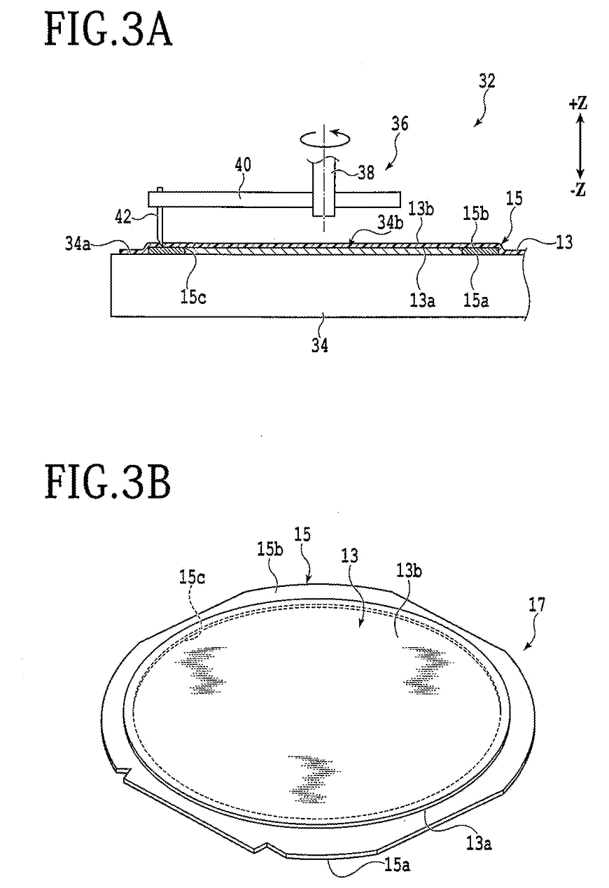

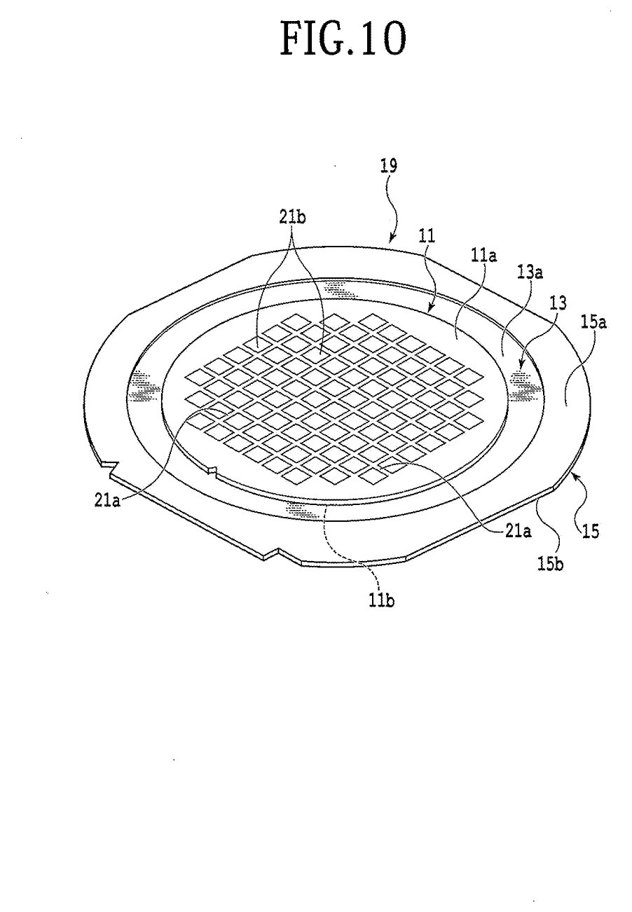

An embodiment according to one mode of the present invention is described with reference to the attached drawings. FIG. 1A is a side view of a sheet affixing apparatus 2 that forms a work unit 19 (see FIG. 10) by affixing a sheet 13 configuring a frame unit 17 (see FIG. 3B) to a workpiece 11.

For example, this sheet affixing apparatus 2 is used when the sheet 13 of the frame unit 17 is to be affixed to a reverse side 11b of the workpiece 11 which has a face side 11a to which an unillustrated resin protective tape (that is, what is generally called a back grinding tape) for protecting devices 21b (see FIG. 10) formed on the face side 11a of the workpiece 11 is affixed.

Alternatively, this sheet affixing apparatus 2 may be used when the sheet 13 of the frame unit 17 is to be affixed to the reverse side 11b of the workpiece 11 which has the face side 11a to which no protective tape is affixed.

FIG. 1A illustrates some of the components of the sheet affixing apparatus 2 simply in functional blocks. An X-axis, a Y-axis, and a Z-axis illustrated in FIG. 1A are orthogonal to one another. In FIG. 1A, a positive direction on the X-axis is a +X direction, while a negative direction on the X-axis is a –X direction. The +X direction and the –X direction are directions opposite to each other.

Further, in FIG. 1A, a positive direction on the Y-axis is a +Y direction, while a negative direction on the Y-axis is a –Y direction. The +Y direction and the –Y direction are directions parallel and opposite to each other. Similarly, a positive direction on the Z-axis is a +Z direction, while a negative direction on the Z-axis is a –Z direction. The +Z direction and the –Z direction are directions parallel and opposite to each other.

In the present specification, the +X direction and the -X direction are collectively referred to as the X-axis direction, the +Y direction and the -Y direction are collectively referred to as the Y-axis direction, and the +Z direction and the -Z direction are collectively referred to as the Z-axis direction. Further, the -Z direction is a vertical direction (that is, the gravity direction), and the -Z direction is sometimes referred to as the downward direction, while the +Z direction is sometimes referred to as the upward direction.

When the Z-axis direction is parallel to the vertical direction, an XY plane orthogonal to the Z-axis direction is parallel to a horizontal plane. Note that, unless otherwise specifically described, in each figure, the +Z direction means the upward direction, and the -Z direction means the downward direction.

The sheet affixing apparatus 2 includes a disk-shaped work holding table 4. The work holding table 4 is a chuck table that holds a workpiece under suction by negative pressure. The work holding table 4 has a disk-shaped frame body 6a formed of metal such as stainless steel (see FIG. 1B).

In a central portion of the frame body 6a in a radial direction, a disk-shaped recessed portion having a diameter smaller than an outside diameter of the frame body 6a is formed. In the recessed portion of the frame body 6a, a disk-shaped porous plate 6b (see FIG. 1B) formed of porous ceramic is disposed. The porous plate 6b is fixed to the frame body 6a with use of an adhesive agent or the like.

While most part of the porous plate 6b is covered with the frame body 6a, only a lower surface of the porous plate 6b is exposed from the frame body 6a. To the frame body 6a, a suction source 8 such as an ejector or a vacuum pump is connected, and the negative pressure from the suction source 8 is transmitted to the lower surface of the porous plate 6b via the frame body 6a.

Between the suction source 8 and the frame body 6a, an unillustrated first solenoid valve for controlling whether or not to transmit the negative pressure from the suction source 8 to the porous plate 6b is provided. When the first solenoid valve is opened, negative pressure is transmitted from the suction source 8 to the lower surface of the porous plate 6b.

A lower surface of the frame body 6a and the lower surface of the porous plate 6b are substantially flush with each other and configure a work holding surface 4a for holding under suction the workpiece 11 described above. According to the present embodiment, a thickness direction 4c of the work holding table 4 is parallel to the -Z direction, and the work holding surface 4a is disposed in a downward direction to face straight downward.

According to the present embodiment, the thickness direction 4c of the work holding table 4 is a direction of moving straight downward from the work holding surface 4a along the Z-axis direction; the thickness direction 4c is also a direction of moving toward the circular work holding surface 4a from a circular upper surface 4d in the work holding table 4.

Note that, even when the work holding surface 4a cannot be evaluated as being flat in a strict sense due to irregularities, waviness, or the like present on the work holding surface 4a, the direction of moving from the upper surface 4d toward the work holding surface 4a can be regarded as the thickness direction 4c of the work holding table 4.

Needless to say, a normal vector relative to a virtual plane that is in contact with the work holding surface 4a and that is parallel to the XY plane is also parallel to the -Z direction. As described above, one of the major features of the present embodiment is that the work holding surface 4a is facing straight downward.

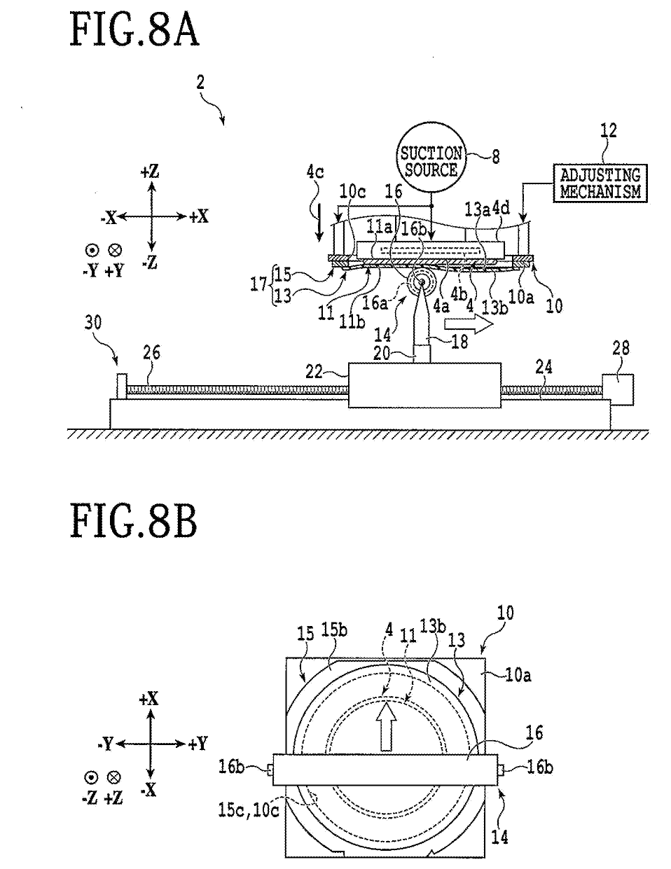

Inside the frame body 6a, there is provided a heater (i.e., a second heating section) 4b such as a cartridge heater. The heater 4b generates heat upon receiving electric power supplied from an unillustrated power supply section. Heating the work holding table 4 by the heater 4b heats and softens the sheet 13 when the sheet 13 is affixed to the workpiece 11 (see FIG. 8A), improving the adhesiveness of the sheet 13 with respect to the workpiece 11.

Moreover, at the time of affixing the sheet 13 to the workpiece 11, a heater (i.e., a first heating section) 16a that is provided in a pressing roller 16 to be described later may be caused to generate heat, in place of or together with the heater 4b. That is, at the time of affixing the sheet 13 to the workpiece 11, one of or both the heater 4b and the heater 16a provided in the sheet affixing apparatus 2 may be used.

Note that the sheet 13 is preferably heated to improve the adhesiveness between the workpiece 11 and the sheet 13, but heating is not essential; one of or both the heater 4b and the heater 16a may be omitted. Even when the heater 4b and the heater 16a are not used, the sheet 13 including an adhesive layer can be affixed to the workpiece 11.

On an outer circumferential portion of the work holding table 4, an annular frame holding table 10 is provided in such a manner as to surround the work holding table 4. The frame holding table 10 has a lower surface that is substantially flat and that functions as a frame holding surface 10a for holding under suction a frame 15 (see FIG. 3B) of the frame unit 17 described above. The frame holding surface 10a is also substantially parallel to the XY plane.

FIG. 1B is a bottom view of the work holding table 4 and the frame holding table 10. The frame holding surface 10a is substantially flat but has a plurality of suction ports 10b to which negative pressure is transmitted from the suction source 8 and each of which has a small diameter. The frame holding surface 10a according to the present embodiment has a rectangular outer shape, and the plurality of suction ports 10b are provided at each of four corners of the frame holding surface 10a.

Between the suction source 8 and the frame holding table 10, there is provided an unillustrated second solenoid valve for controlling whether or not to transmit negative pressure from the suction source 8 to the frame holding table 10. When the second solenoid valve is opened, negative pressure is transmitted from the suction source 8 to each of the suction ports 10b.

Yet, the frame holding table 10 is not limited to being configured in the mode illustrated in FIG. 1B. The frame 15 may be held on the frame holding surface 10a by one of or both suction using negative pressure, magnetic force, or the like and mechanical fixation using a ring, a claw portion, or the like. Moreover, the frame holding surface 10a may be provided with protruding portions, recessed portions, or the like for positioning the frame 15 with respect to the frame holding surface 10a.

The frame holding surface 10a has an opening 10c at its central portion in the radial direction. The opening 10c has a diameter larger than that of the work holding surface 4a and is disposed concentrically with the work holding surface 4a.

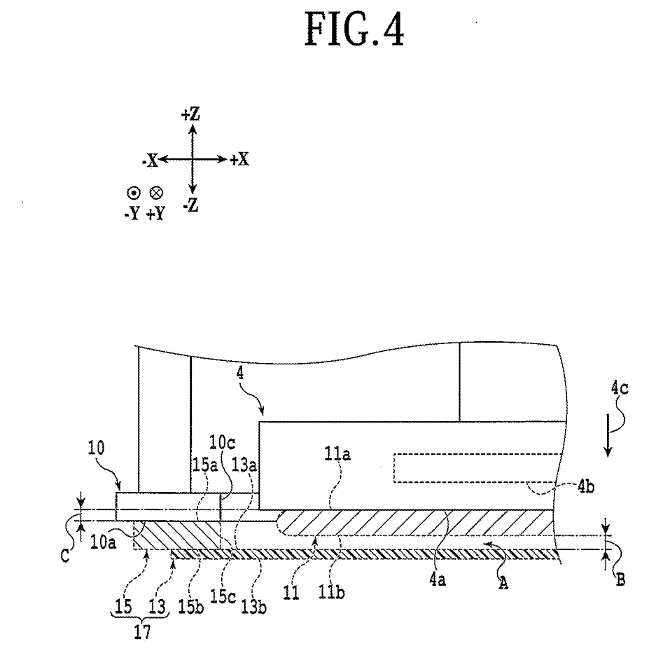

As illustrated in an enlarged manner in FIG. 4, the frame holding surface 10a is protruding more than the work holding surface 4a in the thickness direction 4c of the work holding table 4 (that is, the -Z direction). That is, the frame holding surface 10a is disposed at a lower position than the work holding surface 4a.

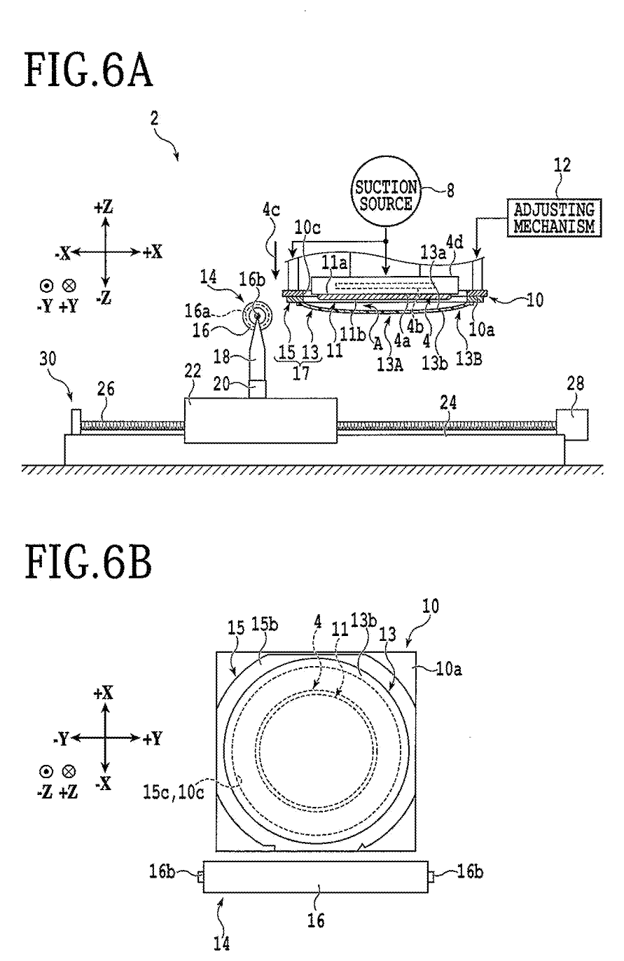

Hence, when the frame 15 is held under suction on the frame holding surface 10a and the workpiece 11 is held under suction on the work holding surface 4a, the workpiece 11 and the sheet 13 at the central portion of the frame 15 face each other at a distance from each other, and the sheet 13 bends such that a central portion 13A of the sheet 13 in the radial direction is farther from the workpiece 11 than an outer circumferential portion 13B of the sheet 13 in the radial direction (see FIG. 6A).

That is, the distance between the central portion 13A of the sheet 13 and the workpiece 11 is greater than the distance between the outer circumferential portion 13B of the sheet 13 and the workpiece 11. The central portion 13A of the sheet 13 is a circular region including the center of the sheet 13 in the radial direction and having a predetermined radius (for example, 5.0 mm).

Further, the outer circumferential portion 13B of the sheet 13 is a circular ring-shaped region having a predetermined width (for example, 5.0 mm) from an opening 15c of the frame 15 toward the center of the sheet 13 in the radial direction. Bending of the sheet 13 forms a gap A between the workpiece 11 and the sheet 13 (see FIGS. 4 and 6A). The gap A has a length B of not less than 500 μm in the Z-axis direction (see FIG. 4).

In one example, when the thickness of the workpiece 11 is in a range of 725 μm to 770 μm and the thickness of the frame 15 (that is, the length from a reverse side 15b to a face side 15a) is 1000 μm, causing the frame holding surface 10a to protrude downward more than the work holding surface 4a by a length C (see FIG. 4) in the range of 270 μm to 275 μm makes the length B of the gap A fall within the range of 505 μm to 545 μm.

Note that the abovementioned numerical range of the length B is one in an ideal case where the sheet 13 does not sag due to action of gravity, and in practice, the central portion 13A of the sheet 13 sags downward compared to the outer circumferential portion 13B of the sheet 13 fixed to the frame 15, so that the length B of the gap A increases toward the central portion 13A of the sheet 13 in the radial direction. Description will now return to FIG. 1A.

The sheet affixing apparatus 2 includes an adjusting mechanism 12 that moves the frame holding table 10 and the work holding table 4 relative to each other along the Z-axis direction. The adjusting mechanism 12 includes, for example, a ball screw including guide rails, a screw shaft, a nut, a servomotor, and the like, but may instead include other mechanisms such as an air cylinder.

While the adjusting mechanism 12 according to the present embodiment moves the frame holding table 10 along the Z-axis direction, the adjusting mechanism 12 may alternatively move the work holding table 4 along the Z-axis direction or move both the frame holding table 10 and the work holding table 4 along the Z-axis direction.

By the adjusting mechanism 12 adjusting the position of the frame holding surface 10a relative to the work holding surface 4a in the Z-axis direction, the abovementioned length B is adjusted. Below the work holding table 4 and the frame holding table 10, a pressing mechanism 14 that presses the sheet 13 and other members upward is disposed.

The pressing mechanism 14 includes a cylindrical pressing roller (that is, a pressing member) 16 whose longitudinal direction is arranged along the Y-axis. Provided inside the pressing roller 16 is the heater 16a such as a cartridge heater. FIG. 1A illustrates an outline of the heater 16a by a dashed line.

Both end portions 16b of the pressing roller 16 in the longitudinal rection are supported in a rotatable manner by upper end portions of a pair of support sections 18. The pair of support sections 18 are supported in a movable manner in the Z-axis direction by an elastic mechanism 20.

The elastic mechanism 20 includes an elastic member using hydraulic pressure, air pressure, spring, and the like and can exert restoring force. For example, when the pressing roller 16 receives downward force, the elastic mechanism 20 pushes back the pressing roller 16 upward. Thus, when the sheet 13 and other members are pressed, the upper end position of the pressing roller 16 is finely adjusted in the Z-axis direction.

The elastic mechanism 20 is supported on an X-axis direction moving plate 22. Provided below the X-axis direction moving plate 22 are a pair of X-axis direction guide rails 24 that support the X-axis direction moving plate 22 in a slidable manner. Note that FIG. 1A illustrates one of the pair of X-axis direction guide rails 24.

Between the pair of X-axis direction guide rails 24, there is provided a screw shaft 26 whose longitudinal portion is arranged along the X-axis. Below the X-axis direction moving plate 22, an unillustrated nut portion is provided. The screw shaft 26 is coupled to this nut portion in a rotatable manner through a plurality of unillustrated balls. The screw shaft 26 has one end portion coupled to a drive source 28 such as a servomotor.

When the drive source 28 is actuated, the X-axis direction moving plate 22 moves along the X-axis direction. The X-axis direction moving plate 22, the pair of X-axis direction guide rails 24, the nut portion, the screw shaft 26, and other relevant members configure a linear mechanism (moving mechanism) 30. The linear mechanism 30 has a function of linearly moving a transferred body (the pressing mechanism 14 in the present example) supported by the X-axis direction moving plate 22, in a predetermined direction (the X-axis direction in the present example).

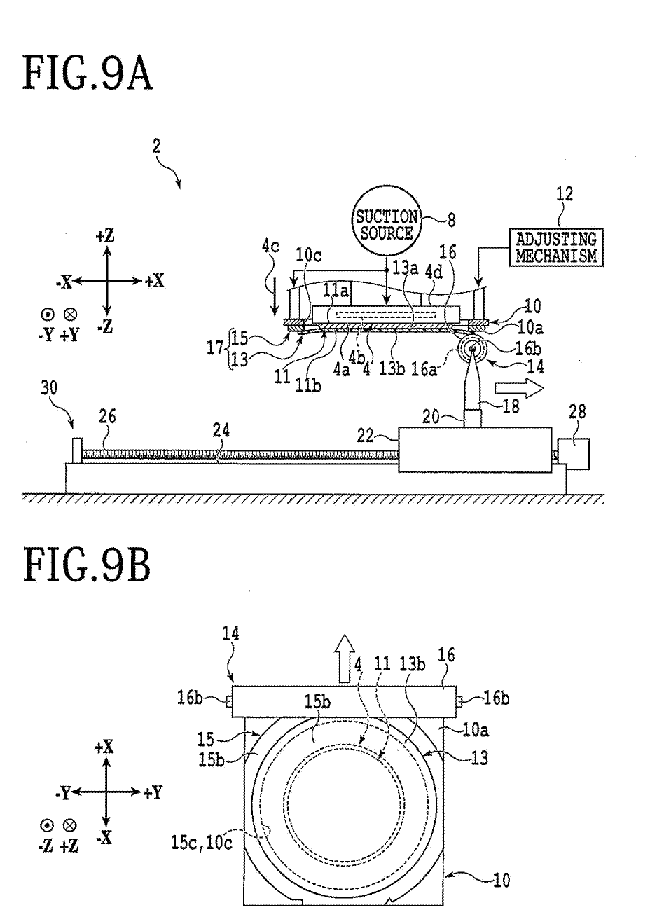

With the linear mechanism 30 moving the pressing roller 16 relative to the work holding table 4 and the frame holding table 10 in the X-axis direction in a state in which the sheet 13 of the frame unit 17 held by the frame holding table 10 is sandwiched between the workpiece 11 held by the work holding surface 4a and the pressing roller 16 and is pressed by the pressing roller 16 against the workpiece 11, the sheet 13 can be affixed to the workpiece 11 (see FIGS. 8A through 9B).

In the sheet affixing apparatus 2 according to the present embodiment, for example, the central portion 13A of the sheet 13 gets farther from the workpiece 11 than the outer circumferential portion 13B of the sheet 13 by the weight of the sheet 13 itself due to the action of gravity, so that a portion of the sheet 13 can be prevented from coming into contact with the workpiece 11 prior to pressing of the sheet 13 against the workpiece 11 by the pressing roller 16. Thus, the possibility of air bubbles, wrinkles, or the like being formed in the sheet 13 when a work unit 19 is formed can be reduced.

The sheet affixing apparatus 2 includes an unillustrated controller that controls the operations of the first and second solenoid valves, the adjusting mechanism 12, the pressing mechanism 14, the linear mechanism 30, and other members. The controller includes, for example, a computer including a processor typified by a central processing unit (CPU) and a memory.

The memory includes a main storage device such as a dynamic random access memory (DRAM) and an auxiliary storage device such as a flash memory, a hard disk drive, and a solid state drive. In the auxiliary storage device, software including a predetermined program is stored. When the processor and other members are operated according to this software, the functions of the controller are implemented.

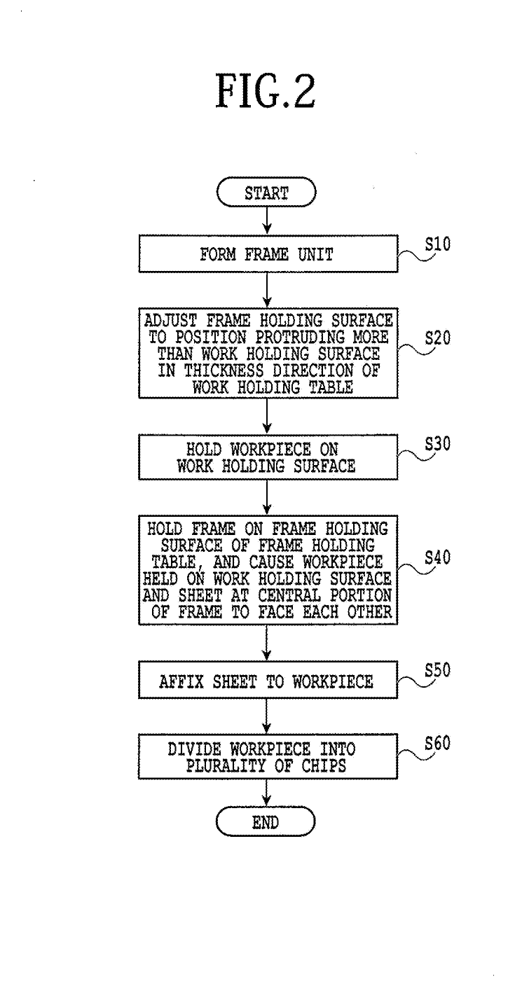

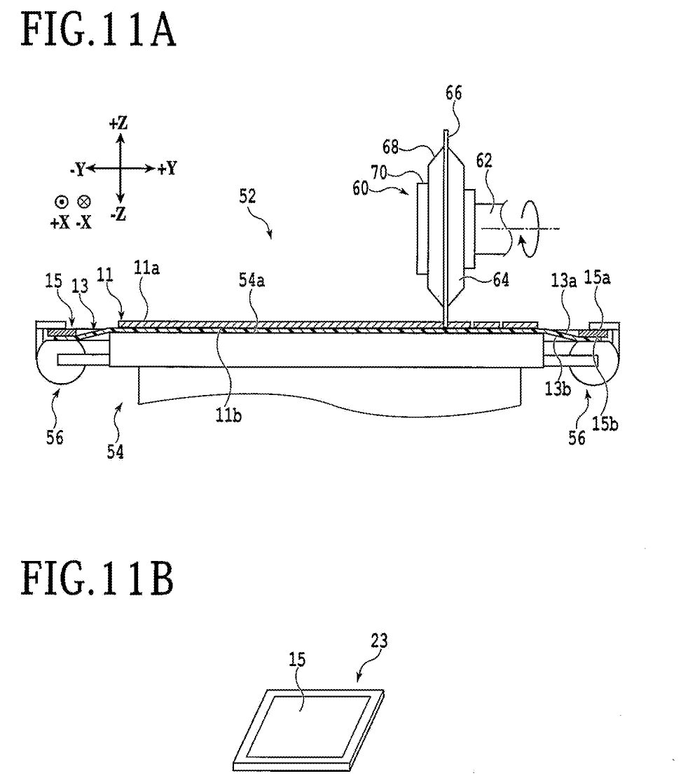

Next, a method of manufacturing device chips 23 (see FIG. 11B) by dividing the workpiece 11 into a plurality of device chips (that is, chips) 23 is described with reference to FIGS. 2 through 11B. FIG. 2 is a flowchart illustrating the method of manufacturing the device chips 23. Note that the method of manufacturing the device chips 23 includes a method of, with respect to the frame unit 17 including the frame 15 and the sheet 13, affixing the sheet 13 at a central portion of the frame 15 to the reverse side 11b of the workpiece 11.

According to the present embodiment, the steps are, in principle, performed in the order of S10 to S60. FIG. 3A is a side view illustrating a frame unit forming step S10 of forming the frame unit 17 by affixing an outer circumferential portion of the sheet 13 to the reverse side (that is, one surface) 15b of the frame 15 in a manner closing the opening 15c at the central portion of the frame 15.

The frame unit forming step S10 is performed before a work holding step S30 of holding the workpiece 11 under suction on the work holding surface 4a. In the frame unit forming step S10 according to the present embodiment, an affixing apparatus 32 different from the sheet affixing apparatus 2 is used.

The affixing apparatus 32 includes a holding table (that is, another holding table) 34 that is different from the work holding table 4 and the frame holding table 10. As described above, using the holding table 34 can improve the unit per hour (UPH) compared to the case of using the work holding table 4 and the frame holding table 10 for both the frame unit 17 and the work unit 19.

However, when a plurality of work units 19 are not planned to be formed sequentially (that is, when UPH need not be taken into consideration), both the frame unit 17 and the work unit 19 may be formed by the sheet affixing apparatus 2.

On an upper surface 34a of the holding table 34, a disk-shaped protruding portion 34b having a thickness substantially the same as the thickness of the frame 15 and a diameter substantially the same as the diameter of the opening 15c of the frame 15 is provided. Note that the protruding portion 34b is not essential and may be omitted.

Provided on an outer side of the protruding portion 34b on the upper surface 34a is an unillustrated positioning member for determining the orientation of the frame 15. Using the protruding portion 34b and the positioning member makes it possible to uniquely determine the position and orientation of the frame 15 on the upper surface 34a.

Uppermost surfaces of the upper surface 34a, the protruding portion 34b, and the positioning member are covered with fluorine resin, i.e., fluoropolymer, such as polytetrafluoroethylene, so that, even if the adhesive layer of the sheet 13 comes into contact with such members, the sheet 13 can easily be peeled off. The sheet 13 according to the present embodiment is a dicing tape made from resin.

The sheet 13 has, for example, a layered structure including an adhesive layer formed of ultraviolet (UV)-curing acrylic resin and a base layer formed of polyolefin, polyvinyl chloride, or the like. The exposed surface of the adhesive layer is an adhesive surface 13a of the sheet 13, while the exposed surface of the base layer is a non-adhesive surface 13b of the sheet 13. However, the sheet 13 may include no adhesive layer and only the base layer formed of thermoplastic resin such as polyolefin.

Above the holding table 34, an unillustrated pressing roller is provided and presses the long sheet 13 having a width greater than the outer shape of the frame 15 against the reverse side 15b of the frame 15 whose position is fixed on the holding table 34, to affix the sheet 13 to the reverse side 15b.

As a result, the sheet 13 is affixed to the reverse side 15b of the frame 15 in a manner closing the opening 15c at the central portion of the frame 15. Next, the sheet 13 is cut out in a circular shape by a cutting mechanism 36 provided above the holding table 34.

The cutting mechanism 36 has a rotational shaft 38 to which power is transmitted from an unillustrated motor. To the rotational shaft 38, a proximal end portion of an arm section 40 that is disposed such that its longitudinal portion intersects the shaft center at right angles is fixed. The arm section 40 has a distal end portion to which a cutting edge 42 is fixed. The cutting edge 42 protrudes downward from the distal end portion of the arm section 40.

When the rotational shaft 38 is rotated in a state in which the distal end portion of the cutting edge 42 has cut into the sheet 13 positioned on the reverse side 15b of the frame 15, the sheet 13 is cut out in a circular shape having a diameter greater than that of the opening 15c. FIG. 3B is a perspective view of the frame unit 17 formed in this manner.

According to the present embodiment, after the frame unit forming step S10 but before the work holding step S30 of holding the workpiece 11 under suction on the work holding surface 4a, a relative moving step S20 of adjusting the frame holding surface 10a to a position protruding more than the work holding surface 4a in the thickness direction 4c is performed. Yet, the frame unit forming step S10 may instead be performed after the relative moving step S20.

FIG. 4 is a view illustrating the relative moving step S20 of moving the frame holding surface 10a and the work holding surface 4a relative to each other. In the relative moving step S20, the frame holding table 10 and the work holding table 4 are moved relative to each other in the thickness direction 4c of the work holding table 4.

More specifically, in the relative moving step S20, the adjusting mechanism 12 moves the frame holding table 10 along the Z-axis direction, for example, to cause the frame holding surface 10a to protrude downward more than the work holding surface 4a by 270 μm to 275 μm.

Note that, as described above, the work holding table 4 may be moved along the Z-axis direction, or both the frame holding table 10 and the work holding table 4 may be moved along the Z-axis direction.

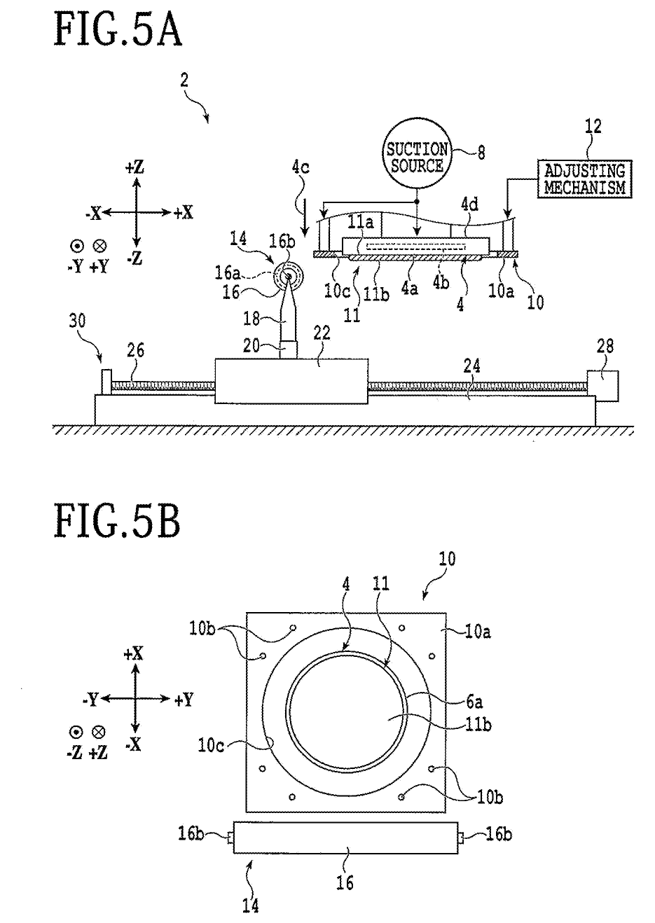

After the relative moving step S20, the workpiece 11 is held under suction on the work holding surface 4a of the work holding table 4 such that the reverse side 11b of the workpiece 11 is exposed downward (work holding step S30). FIG. 5A is a view illustrating the work holding step S30, while FIG. 5B is a bottom view of the workpiece 11, the work holding table 4, and the frame holding table 10 in the work holding step S30.

After the work holding step S30, the frame unit holding step S40 is performed. In the frame unit holding step S40, the frame 15 is held under suction on the frame holding surface 10a of the frame holding table 10.

As a result, the reverse side 11b of the workpiece 11 held under suction on the work holding surface 4a and the sheet 13 at the central portion of the frame 15 are caused to face each other at a distance from each other in a state in which the sheet 13 is bent such that the central portion 13A of the sheet 13 is farther from the reverse side 11b of the workpiece 11 than the outer circumferential portion 13B of the sheet 13.

FIG. 6A is a view illustrating the frame unit holding step S40, while FIG. 6B is a bottom view of the frame unit 17 and other members in the frame unit holding step S40. In the frame unit holding step S40, as described above, the gap A is formed between the workpiece 11 and the sheet 13. Note that FIG. 6A illustrates the bending of the sheet 13 in an exaggerated manner compared to FIG. 4.

After the frame unit holding step S40, an affixing step S50 is performed. In the affixing step S50, first, an upper end of the pressing roller 16 is positioned slightly (for example, 1 mm) above the reverse side 11b of the workpiece 11 in the Z-axis direction.

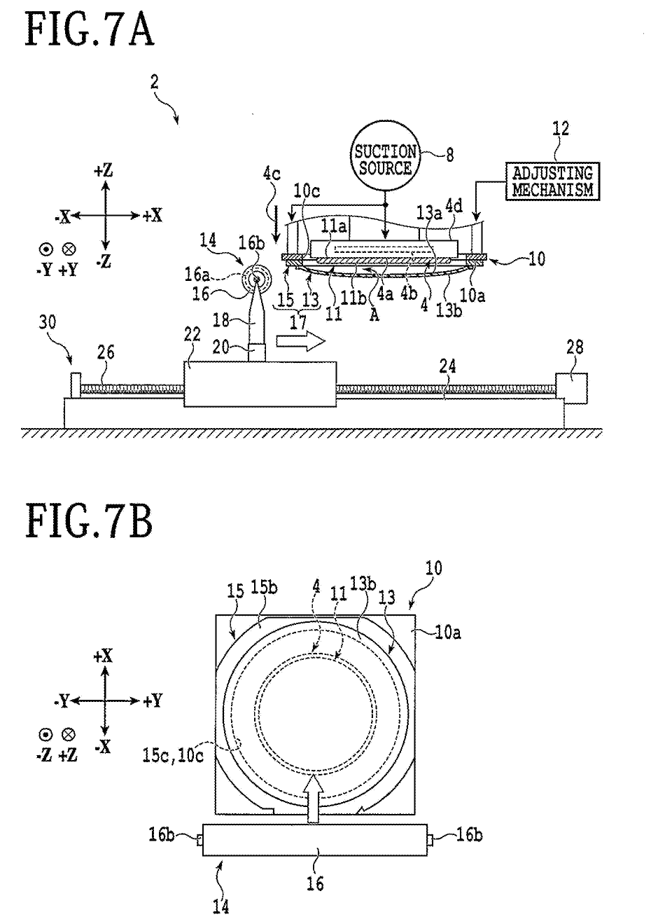

In this state, the X-axis direction moving plate 22 is moved along the X-axis direction at a predetermined speed (for example, 10 mm/s or faster but 30 mm/s or slower), to bring the pressing roller 16 close to the workpiece 11 in the X-axis direction (see FIGS. 7A and 7B).

FIG. 7A is a view illustrating the state at the time when the affixing step S50 of affixing the sheet 13 to the workpiece 11 is started, while FIG. 7B is a bottom view of the frame unit 17 and other members at the time when the affixing step S50 is started.

In the affixing step S50, the X-axis direction moving plate 22 is continuously moved in the +X direction in a state in which the sheet 13 is sandwiched between the pressing roller 16 and the workpiece 11 and is pressed against the workpiece 11 by the pressing roller 16.

That is, the pressing roller 16 is moved relative to the work holding table 4 and the frame holding table 10 along the X-axis direction. As a result, the sheet 13 is affixed to the workpiece 11. Further, in the affixing step S50, the sheet 13 is affixed to the workpiece 11 in a state in which both or one of the pressing roller 16 and the work holding surface 4a is heated.

When heated to a predetermined temperature (for example, 80ºC to 100ºC) by heating, the sheet 13 becomes soft, enhancing the adhesiveness of the sheet 13 with respect to the workpiece 11 at the time of affixing the sheet 13 to the workpiece 11.

As described above, the sheet 13 is preferably heated to improve the adhesiveness between the sheet 13 and the workpiece 11, but heating is not essential, and one of or both the heater 4b and the heater 16a may be omitted.

FIG. 8A is a view illustrating the state in the middle of the affixing step S50, while FIG. 8B is a bottom view of the frame unit 17 and other members in the middle of the affixing step S50. FIG. 9A is a view illustrating the state at the time when the affixing step S50 is ended, while FIG. 9B is a bottom view of the frame unit 17 and other members at the time when the affixing step S50 is ended.

According to the present embodiment, the sheet 13 gets farther from the workpiece 11 by its own weight due to the action of gravity, so that a portion of the sheet 13 can be prevented from coming into contact with the workpiece 11 prior to pressing of the sheet 13 against the workpiece 11 by the pressing roller 16. Thus, the possibility of air bubbles, wrinkles, or the like being formed in the sheet 13 when the work unit 19 is formed may be reduced.

FIG. 10 is a perspective view of the work unit 19 formed in the affixing step S50. As illustrated in FIG. 10, a plurality of projected dividing lines 21a are set in such a manner as to intersect each other at right angles (that is, to cross each other) on the face side (that is, one surface) 11a of the workpiece 11, and devices 21b are each formed in each of a plurality of rectangular regions partitioned by the plurality of projected dividing lines 21a.

After the work unit 19 is formed, a cutting apparatus 52 (see FIG. 11A) is used to divide the workpiece 11 along each of the projected dividing lines 21a into a plurality of device chips 23.

As illustrated in FIG. 11A, the cutting apparatus 52 includes a disk-shaped chuck table 54 that holds the work unit 19 under suction. The chuck table 54 includes a frame body formed of metal or the like. In a central portion of the frame body in the radial direction, a disk-shaped recessed portion having a diameter smaller than an outside diameter of the frame body is formed.

In this recessed portion of the frame body, an unillustrated disk-shaped porous plate formed of porous ceramic is fixed to the frame body with use of an adhesive agent or the like. While most part of the porous plate is covered with the frame body, only an upper surface of the porous plate is exposed from the frame body.

To the frame body, an unillustrated suction source such as an ejector or a vacuum pump is connected. Negative pressure from the suction source is transmitted to the upper surface of the porous plate via the frame body. An upper surface of the frame body and the upper surface of the porous plate are substantially flush with each other and configure a holding surface 54a.

In the chuck table 54, its thickness direction is parallel to the +Z direction, and the holding surface 54a is disposed in an upward direction to face straight upward. On an outer circumferential portion of the chuck table 54, a plurality of clamp units 56 are provided. Each of the clamp units 56 clamps the frame 15 in the Z-axis direction.

Below the chuck table 54, an unillustrated θ table is provided. The θ table has a rotational shaft disposed along the Z-axis and can rotate the chuck table 54 about this rotational shaft. Below the θ table, an unillustrated X-axis direction moving mechanism is provided.

The X-axis direction moving mechanism includes, similarly to the linear mechanism 30 described above, an X-axis direction moving plate, a pair of X-axis direction guide rails, a nut portion, a screw shaft, and the like, and the X-axis direction moving plate supports the θ table and the chuck table 54. The X-axis direction moving mechanism can move the θ table, the chuck table 54, and other relevant members along the X-axis direction.

Provided above the chuck table 54 is a cutting unit 60. The cutting unit 60 includes a cylindrical spindle 62 whose longitudinal portion is arranged along the Y-axis. The spindle 62 can rotate at high speed by an unillustrated spindle motor.

To a distal end portion of the spindle 62, a mount 64 is fixed with use of unillustrated bolts. The mount 64 includes an unillustrated cylindrical boss portion. The boss portion has a distal end portion in which a male screw is formed. The boss portion of the mount 64 is inserted into opening portions of a cutting blade (a hubless blade in the present example) 66 and a pressing flange 68 each having a circular ring shape.

With a female screw provided in an inner circumferential surface of an opening portion in a circular ring-shaped nut portion 70 and the male screw of the boss portion being fastened to each other, the cutting blade 66 is fixed to the distal end portion of the spindle 62 in a state of being sandwiched between the mount 64 and the pressing flange 68 in the Y-axis direction.

FIG. 11A is a partially sectional side view illustrating a dividing step S60 of dividing the workpiece 11 into a plurality of device chips 23 with use of the cutting apparatus 52. In the dividing step S60, first, the work unit 19 is placed on the chuck table 54.

After the work unit 19 is placed on the chuck table 54, the workpiece 11 is held under suction on the holding surface 54a via the sheet 13, and the frame 15 is clamped by the plurality of clamp units 56.

Next, after the tilt of the projected dividing lines 21a with respect to the X-axis is identified by an unillustrated microscopic camera provided above the holding surface 54a, the orientation of the θ table is adjusted such that the projected dividing lines 21a become substantially parallel to the X-axis direction.

Subsequently, after a lower end of the cutting blade 66 that is rotating at high speed (for example, 25,000 rpm) together with the spindle 62 is disposed on an extension of the relevant projected dividing line 21a and then adjusted to a position between the holding surface 54a and the reverse side 11b in the Z-axis direction, the chuck table 54 is moved at a predetermined processing feed speed (for example, 30 mm/s).

Moving the lower end of the cutting blade 66 and the chuck table 54 relative to each other along the X-axis direction forms a cutting groove (a full-cut groove in the present example) from one end to the other end of the projected dividing line 21a. After the cutting groove is formed in one projected dividing line 21a, the cutting unit 60 is moved in the Y-axis direction by a predetermined index feeding amount.

Then, a cutting groove is similarly formed in another projected dividing line 21a that is adjacent, in the Y-axis direction, to the projected dividing line 21athat has just been cut. After cutting grooves have been formed in all of the projected dividing lines 21a along the X-axis direction in the manner described above, the chuck table 54 is rotated by 90 degrees.

Thereafter, cutting grooves are similarly formed along all of the projected dividing lines 21a extending along the X-axis direction. This forms a plurality of cutting grooves in a grid pattern in the workpiece 11, and the workpiece 11 is divided into a plurality of device chips 23. FIG. 11B is a perspective view of one device chip 23.

According to the present embodiment, the possibility of air bubbles, wrinkles, or the like being formed in the sheet 13 when the work unit 19 is formed can be reduced, so that the possibility of processing defects such as chipping occurring at the time of dividing the workpiece 11, to which the sheet 13 is affixed, can also be reduced.

### Second embodiment

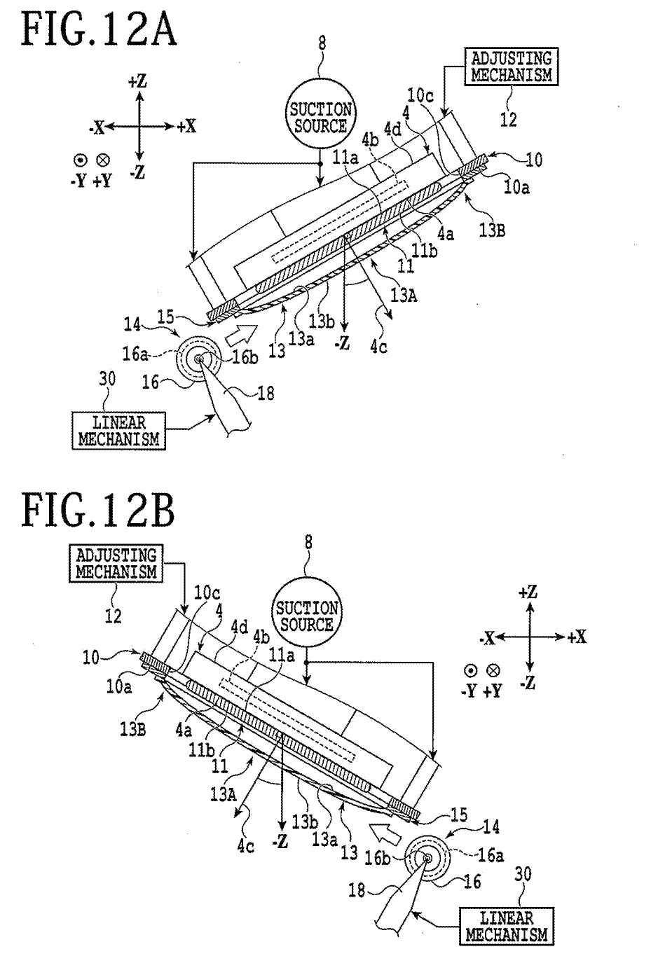

Next, a second embodiment of the present invention is described with reference to FIG. 12A. FIG. 12A also illustrates some of the components of the sheet affixing apparatus 2 simply in functional blocks.

As illustrated in FIG. 12A, the work holding surface 4a according to the second embodiment is disposed to face obliquely downward instead of being disposed to face straight downward. In particular, according to the second embodiment, the work holding table 4 is tilted such that the thickness direction 4c of the work holding table 4 and the -Z direction form an angle of 30 degrees as viewed in an XZ plane.

When the tilt angle formed by the thickness direction 4c and the -Z direction is too large, the possibility of a portion of the sheet 13 coming into contact with the workpiece 11 prior to the start of the affixing step S50 becomes high.

Hence, the tilt angle is preferably 30 degrees at maximum. Needless to say, the angle formed by the thickness direction 4c and the -Z direction as viewed in the XZ plane may fall within the range of 0 to 30 degrees. Note that, according to the present embodiment, the tilt angle means an acute angle formed by the thickness direction 4c of the work holding table 4 and the -Z direction.

Also according to the present embodiment, when the workpiece 11 is held under suction on the work holding surface 4a, the workpiece 11 and the sheet 13 at the central portion of the frame 15 face each other at a distance from each other, and the sheet 13 bends such that the central portion 13A of the sheet 13 in the radial direction is farther from the workpiece 11 than the outer circumferential portion 13B of the sheet 13 in the radial direction.

FIG. 12A is a view illustrating the state at the time when the affixing step S50 according to the second embodiment is started. In the example illustrated in FIG. 12A, the pressing roller 16 is moved from the lower left to the upper right. Hence, the direction of moving the pressing roller 16 by the linear mechanism 30 is adjusted such that the direction of moving the pressing roller 16 forms an angle of 30 degrees with the +X direction as viewed in the XZ plane.

The second embodiment can also prevent a portion of the sheet 13 from coming into contact with the workpiece 11 prior to pressing of the sheet 13 against the workpiece 11 by the pressing roller 16, reducing the possibility of air bubbles, wrinkles, or the like being formed in the sheet 13 when the work unit 19 is formed.

Note that the direction of moving the pressing roller 16 is not limited to the example illustrated in FIG. 12A; the pressing roller 16 may be moved from the upper right to the lower left illustrated in FIG. 12A. In this case, the direction of moving the pressing roller 16 and the -X direction form an angle of 30 degrees as viewed in the XZ plane. Needless to say, in the affixing step S50, the sheet 13 may be affixed to the workpiece 11 in a state in which both or one of the pressing roller 16 and the work holding surface 4a is heated.

### Modification

FIG. 12B is a view illustrating the state at the time when the affixing step S50 according to a modification of the second embodiment is started. FIG. 12B also illustrates some of the components of the sheet affixing apparatus 2 simply in functional blocks.

Also according to the modification of the second embodiment, the work holding surface 4a is disposed to face obliquely downward instead of being disposed to face straight downward, and the thickness direction 4c and the -Z direction form an angle of 30 degrees as viewed in the XZ plane.

However, according to the modification of the second embodiment, a moving direction implemented by the linear mechanism 30 is adjusted such that the direction of moving the pressing roller 16 and the -X direction form an angle of 30 degrees as viewed in the XZ plane.

Note that the configuration is not limited thereto, and the pressing roller 16 may be moved from the upper left to the lower right illustrated in FIG. 12B. In this case, the direction of moving the pressing roller 16 and the +X direction form an angle of 30 degrees as viewed in the XZ plane.

Besides, structures, methods, and other matters according to the embodiments can be implemented by being modified as appropriate within the scope of object of the present invention. In the first and second embodiments, the pressing roller 16 is moved with the spatial positions of the work holding table 4 and the frame holding table 10 being fixed. Alternatively, the work holding table 4 and the frame holding table 10 may be moved with the spatial position of the pressing roller 16 being fixed, or all of the pressing roller 16, and the work holding table 4 and the frame holding table 10 may be moved.

Moreover, in the second embodiment, the sheet 13 can be affixed to the workpiece 11 by the pressing roller 16, by the work holding table 4 and the frame holding table 10 being pressed down in the -Z direction and the pressing roller 16 being moved in the X-axis direction according to this pressing down speed.

Incidentally, devices 21b may not each be formed in each of the plurality of rectangular regions partitioned by the plurality of projected dividing lines 21a on the face side 11a of the workpiece 11. For example, a single-crystal silicon substate including no device 21b may be used as the workpiece 11.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A sheet affixing apparatus that, with respect to a frame unit including an annular frame and a sheet affixed to the frame in a manner closing an opening at a central portion of the frame, affixes the sheet at the central portion of the frame to a workpiece, the sheet affixing apparatus comprising:
a work holding table including a work holding surface that holds the workpiece;
a frame holding table including a frame holding surface that is disposed in such a manner as to surround the work holding table and that holds the frame of the frame unit, and holding the frame on the frame holding surface in a state in which the workpiece held on the work holding surface and the sheet at the central portion of the frame face each other at a distance from each other and the sheet is bent such that a central portion of the sheet is farther from the workpiece than an outer circumferential portion of the sheet;
a pressing member that sandwiches the sheet held by the frame holding table between the pressing member and the workpiece held by the work holding surface, and presses the sheet against the workpiece; and
a moving mechanism that affixes the sheet to the workpiece by moving the pressing member, and the work holding table and the frame holding table relative to one another in a state in which the pressing member is pressing the sheet against the workpiece.

2. The sheet affixing apparatus according to claim 1, wherein the work holding surface is disposed to face downward or obliquely downward.

3. The sheet affixing apparatus according to claim 1, wherein the frame holding surface is protruding more than the work holding surface in a thickness direction of the work holding table.

4. The sheet affixing apparatus according to claim 1, further comprising:
an adjusting mechanism that adjusts a position of the frame holding surface relative to the work holding surface by moving the work holding table and the frame holding table relative to each other along a thickness direction of the work holding table.

5. The sheet affixing apparatus according to claim 1, wherein a thickness direction of the work holding table and a vertical direction as a downward direction form an angle of 30 degrees or less.

6. The sheet affixing apparatus according to claim 1, further comprising:
both or one of a first heating section that heats the pressing member and a second heating section that heats the work holding table.

7. A sheet affixing method that, with respect to a frame unit including an annular frame and a sheet affixed to the frame in a manner closing an opening at a central portion of the frame, affixes the sheet at the central portion of the frame to a workpiece, the sheet affixing method comprising:
holding the workpiece on a work holding surface of a work holding table that holds the workpiece;
after the workpiece is held on the work holding surface, holding the frame on a frame holding surface that is included in a frame holding table, that is disposed in such a manner as to surround the work holding table, and that holds the frame of the frame unit, and causing the workpiece held on the work holding surface and the sheet at the central portion of the frame to face each other at a distance from each other in a state in which the sheet is bent such that a central portion of the sheet is farther from the workpiece than an outer circumferential portion of the sheet; and
after the frame is held on the frame holding surface, affixing the sheet to the workpiece by moving a pressing member, and the work holding table and the frame holding table relative to one another in a state in which the sheet is sandwiched between the pressing member and the workpiece and is pressed against the workpiece by the pressing member.

8. The sheet affixing method according to claim 7, wherein the work holding surface is disposed to face downward or obliquely downward.

9. The sheet affixing method according to claim 7, further comprising:
before the workpiece is held on the work holding surface, forming the frame unit by affixing an outer circumferential portion of the sheet to one surface of the frame in a manner closing the opening at the central portion of the frame, with use of a holding table different from the work holding table and the frame holding table.

10. The sheet affixing method according to claim 7, further comprising:
before the sheet is affixed to the workpiece, adjusting the frame holding surface to a position protruding more than the work holding surface in a thickness direction of the work holding table, by moving the frame holding table and the work holding table relative to each other in the thickness direction of the work holding table.

11. The sheet affixing method according to claim 7, wherein, in the affixing the sheet to the workpiece, the sheet is affixed to the workpiece in a state in which both or one of a first heating section that heats the pressing member and a second heating section that heats the work holding surface is heated.

12. A chip manufacturing method of dividing a workpiece into a plurality of chips after, with respect to a frame unit including an annular frame and a sheet affixed to the frame in a manner closing an opening at a central portion of the frame, affixing the sheet at the central portion of the frame to the workpiece, the chip manufacturing method comprising:
holding the workpiece on a work holding surface of a work holding table that holds the workpiece;
after the workpiece is held on the work holding surface, holding the frame on a frame holding surface that is included in a frame holding table, that is disposed in such a manner as to surround the work holding table, and that holds the frame of the frame unit, and causing the workpiece held on the work holding surface and the sheet at the central portion of the frame to face each other at a distance from each other in a state in which the sheet is bent such that a central portion of the sheet is farther from the workpiece than an outer circumferential portion of the sheet;
after the frame is held on the frame holding surface, affixing the sheet to the workpiece by moving a pressing member, and the work holding table and the frame holding table relative to one another in a state in which the sheet is sandwiched between the pressing member and the workpiece and is pressed against the workpiece by the pressing member; and
after the sheet is affixed to the workpiece, dividing the workpiece into a plurality of chips by dividing the workpiece along a plurality of projected dividing lines that are set on one surface of the workpiece and that intersect each other, the workpiece being provided with a device in each of a plurality of regions partitioned by the plurality of projected dividing lines.
